(19) United States
(12) Patent Application Publication
(10) Pub. No.: US 2008/0079101 A1
(43) Pub. Date: Apr. 3, 2008

(54) INSULATION FRAME DEVICE FOR A STATOR IN A MOTOR

(76) Inventor: CHI AI, Kaohsiung (TW)

Correspondence Address: G. LINK CO., LTD., 3550 BELL ROAD, MINOOKA, IL, 60447, US

(21) Appl. No.: 11/537,961

(22) Filed: Oct. 2, 2006

(51) Int. Cl. H01L 29/84

(52) U.S. Cl. 257/417

(57) ABSTRACT

An insulation frame device for a stator in a motor includes a main member with a bore, extension plates and circular plates. The main member extends from a lateral side of the insulation frame. The extension plates extend radially from the circumferential outer surface of the main member. The outer circular plates are disposed at a free end of the respective extension plate and extend outward circumferentially and oppositely such that a U-shaped space is formed between the extension plates respectively. It is characterized in that the main member provides elastic hooks for engaging a circuit board and first protruding plates are disposed at another lateral side of the insulation frame for locating the silicone steel sheet set with a catching part at the bottom of the first protruding plate to prevent from deformation.

### BACKGROUND OF THE INVENTION

1. Field of the Invention

The present invention is related to an insulation frame device for a stator in a motor and particularly to an insulation frame device, which is capable of enclosing and locating the silicone steel sheet set, preventing from deformation and conveniently engaging with the circuit board with elastic hooks.

2. Brief Description of the Related Art

The conventional insulation frame device such as Chinese Utility Model Publication No. 02201611.2 entitled “INSULATION SLEEVE DEVICE FOR A STATOR OF DC MOTOR” discloses a main body with a central hole and a plurality of extension plates. The extension plates extend radially from the central hole and provide a U shaped receiving groove respectively. The receiving groove has an engaging member extending from two lateral sides of an end thereof for the insulation sleeve device securing the silicone steel sheet set easily.

However, the preceding conventional insulation frame device only engages with the lowermost silicone steel sheet of the whole set and the hub of the silicone set is unable to fit with the main body tightly due to tolerance errors of the main body resulting from fabrication problem. Thus, the silicone steel sheet set in the insulation sleeve creates vibration along circumferential direction once the motor runs to rupture paint coating coils on the extension plates with increasing noise. Further, the locating part of the insulation sleeve for the silicone steel sheet set is deformed easily due to insufficient thickness.

Besides, the engaging hooks on the conventional insulation sleeve are disposed to enclosed a circle with a diameter greater than the inner diameter of the central hole of the circuit board such that it is often to occur problems of damaging the circuit board or the insulation frame.

### SUMMARY OF THE INVENTION

In order to overcome the preceding deficiencies, an object of the present invention is to provide an insulation frame device for a stator in a motor in which elastic hooks are arranged to jut out of an end of the insulation frame and two lateral sides of the respective elastic hook has a slit edge for the insulation frame resiliently engaging with the circuit board flexibly to prevent from rupture of the elastic hooks.

Another object of the present invention is to provide an insulation frame device for a stator in a motor in which each of the first protruding plates has a first catching part next to the center of the insulation frame device to thicken the first protruding plates for preventing from deformation.

Accordingly, an insulation frame device for a stator in a motor according to the present invention includes a first main member with a first bore, first extension plates and circular plates. The main member extends from a lateral side of the insulation frame. The first extension plates extend radially from the circumferential outer surface of the main member. The outer circular plates are disposed at a free end of the respective first extension plate and extend outward circumferentially and oppositely such that a U-shaped space is formed between the extension plates respectively. It is characterized in that the main member provides elastic hooks jutting out of the outer end of the main member for engaging a circuit board and first protruding plates are disposed at another lateral side of the insulation frame for locating the silicone steel sheet set with a catching part at the bottom of the first protruding plate to thicken the first protruding plates for preventing from deformation.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a perspective view of a preferred embodiment of an insulation frame device of a stator in a motor according to the present invention;

FIG. 2 is another perspective view of the insulation frame device shown in FIG. 1;

FIG. 3 is a disassembled perspective view of the first insulation frame and the silicone steel assembly in the insulation frame device of the present invention;

FIG. 4 is a perspective view of the first insulation frame and the silicone steel assembly in the insulation frame device of the present invention;

FIG. 5 is a front view of the first insulation frame and silicone steel assembly shown in FIG. 4;

FIG. 6 is a disassembled perspective view illustrating the insulation frame device of the present invention before being joined to the second insulation frame;

FIG. 7 is a perspective view illustrating the insulation frame device being joined to the second insulation frame;

FIG. 8 is a perspective view illustrating the insulation frame device being wound with coil;

FIG. 9 is a perspective view illustrating the insulation frame device of the invention engaging with a circuit board after being wound with coils;

FIG. 10 is another perspective illustrating the insulation frame device of the invention engaging with a circuit board after being wound with coils; and

FIG. 11 is a sectional view illustrating the insulation frame device of the invention engaging with a circuit board after being wound with coils.

### DETAILED DESCRIPTION OF THE INVENTION

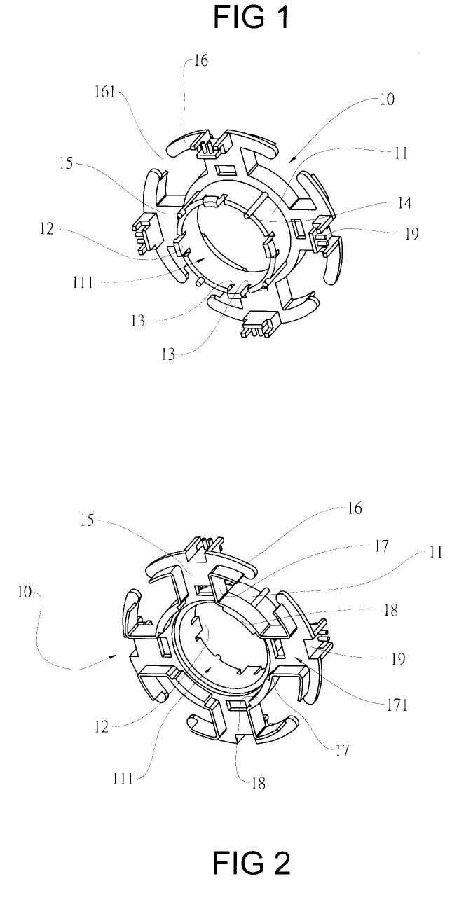

Referring to FIG. 1, an insulation frame device for a stator in a motor according to a preferred embodiment of the present invention provides a first insulation frame 10, which has a first main member 11 extending from a lateral side thereof. The first main member 11 has a first bore 111 and there are a plurality of elastic hooks 12 disposed at the outer end of the main member 11. A slit edge 13 extending to the main member 11 along both lateral sides of the respective elastic hooks 12. A plurality of locating posts 14 are provided on the outer circumferential surface of the main member 11 along the axial direction thereof.

A plurality of first extension plates 15 extend radially from the outer circumferential surface of the main member 11 and it is preferable the first extension plates 15 are disposed to equidistantly space apart from each other. A plurality of first outer circular plates 16 are disposed at the outer ends of the extension plates 15 in a way of two lateral sides of the respective extension plate 15 having one of the first outer circular plates extending circumferentially away the outer end of the respective extension plate 15 such that a first clearance 161 is formed respectively between the respective outer circular plate 16 on the respective extension plate 15 and the respective neighboring outer circular plate 16 on the next extension plate 15 next to it.

Referring to FIG. 2, a plurality of U-shaped protruding plates 17 are disposed at another lateral side of the first insulation frame 10 corresponding to U-shaped spaces between every two of the extension plates 15 with two ends of the respective protruding plate 17 being bent and extending along the outer circular plate 16 next to it. A catching part 18 is provided at the bottom of the respective protruding plate 17 and a first containing groove 171 is formed between any two of the protruding plates 17. Further, a second protruding plate 19 is provided between two opposite outer circular plates 16 to extend from the same lateral side as the main member 11 is disposed.

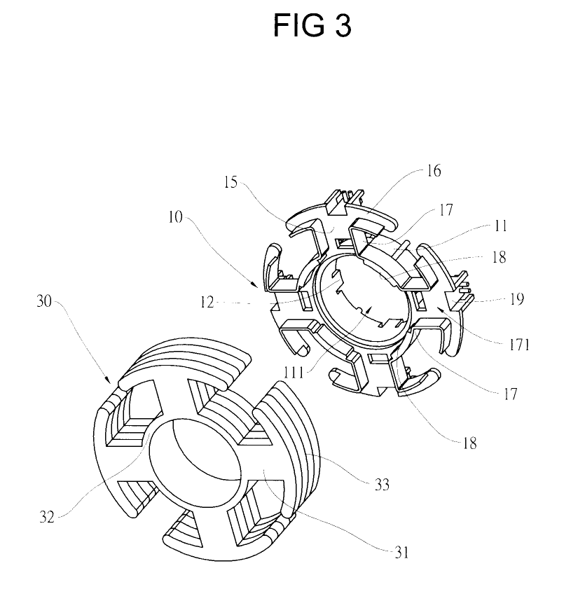

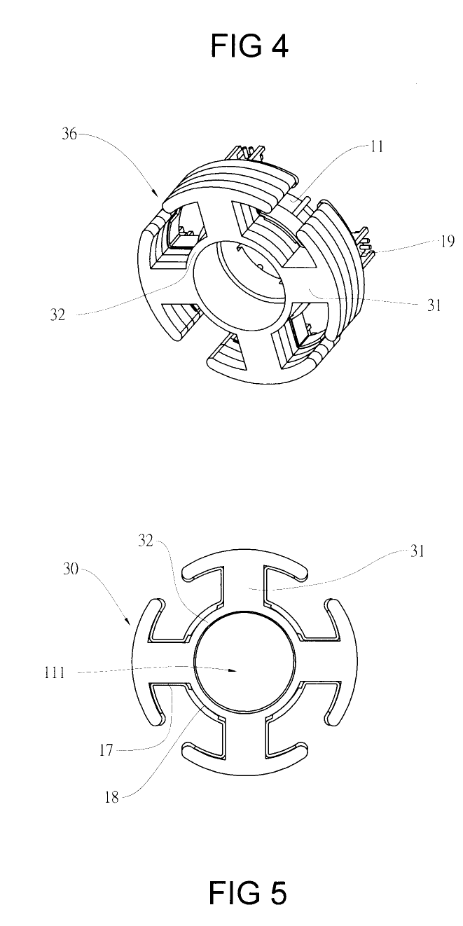

Referring to FIGS. 3, 4 and 5, a silicone steel set 30 provides a contour the same as the first insulation frame 10 and is stacked with the first insulation frame 15 from the anther lateral side of the first insulation frame 15 such that a hub 32 of the silicone steel set 30 engages with the catching pars 18, the pole posts 31 are received in the containing grooves 171 and the pole faces 33 on the pole posts 31 coincide with the first circular plates 16 on the extending plates 15.

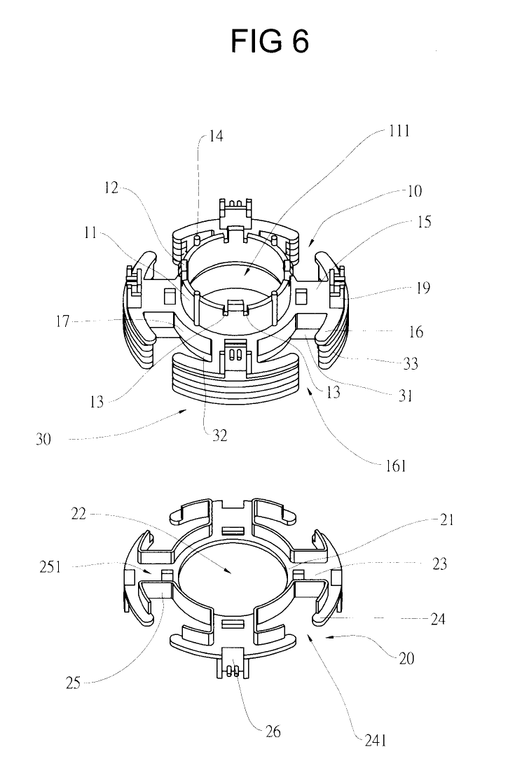

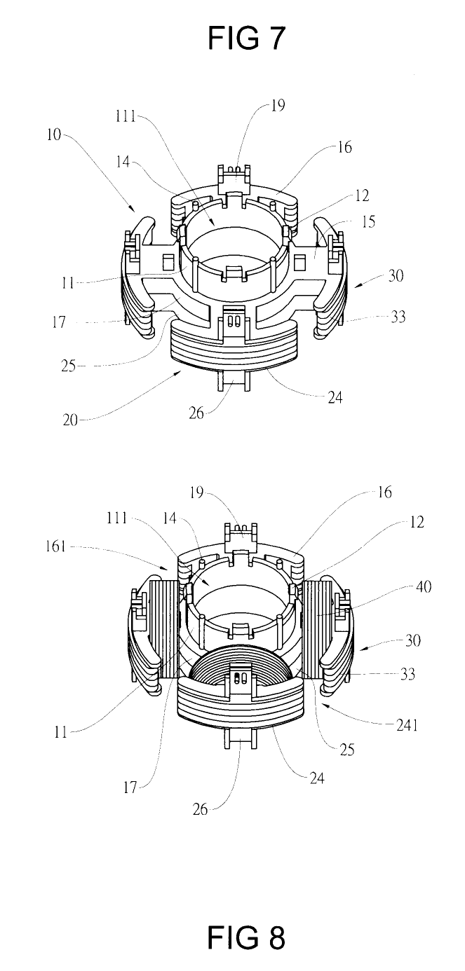

Referring to FIGS. 6 and 7, a second insulation frame 20 is illustrated to be joined to another lateral side of the silicone steel set 30. The second insulation frame 20 has a shape similar to the first insulation frame 10. The second insulation frame 20 provides a joining part 21 with a second bore 22, a plurality of second extension plates 23 corresponding to the first extension plates 15, two opposite second outer circular plates 24 on the respective second extension plate 23 corresponding to the first outer circular plates 16, and a plurality of U-shaped third protruding plates 25 disposed at a lateral side of the second insulation frame 20 facing the another lateral side of the silicone steel set 30 corresponding to the first protruding plates 17. A second clearance 241 is formed respectively between the respective second outer circular plate 24 on the respective second extension plate 23 and the respective neighboring outer circular plate 24 on the second extension plate 23 next to it. A second containing groove 251 is formed between every two adjacent third protruding plates 25 for receiving the pole posts 31. A plurality of fourth protruding plates 26 are provided on the second extension plates 23 extending from another lateral side of the second insulation frame 20 and corresponding to the second protruding plates 19.

When the second insulation frame 20 is attached to the silicone steel set 30, part of the hub 32 of the silicone steel set 30, which does not engage with the catching parts 18, is enclosed by the third protruding plates 25. The pole posts 31 are received in the second containing grooves and the pole surfaces 33 are disposed between the first circular plates 16 and the second circular plates 24.

Referring to FIG. 8 in company with FIGS. 6 and 7, paint coating coils 40 are wound around outer surfaces of the first extension plates 15 and the second extension plates 23 via the first clearance 161 and the second clearance 241. The paint coating coils 40 are gathered and located at the second and fourth protruding plates 19, 26 without releasing outward.

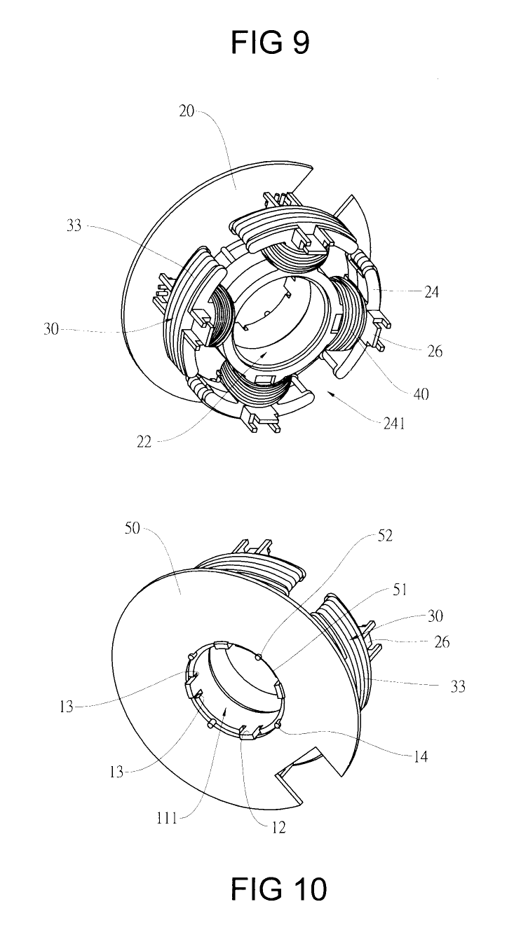

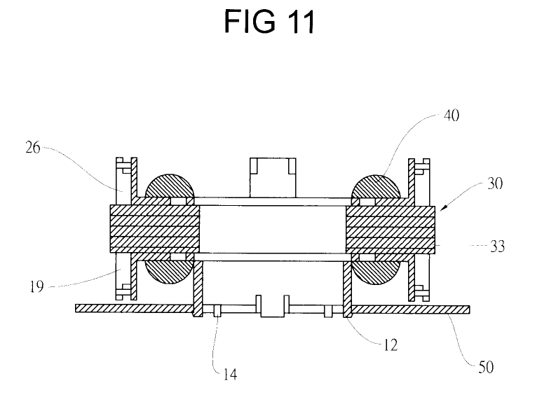

Referring to FIGS. 9 to 11 in company with FIGS. 1 and 7 to 8 again, a circuit board 50 is provided with a fitting bore 51 thereof corresponding to the outer end of the main member 11 and the outer diameter of a circle formed by the elastic hooks 12 being slightly greater than the inner diameter of the fitting bore 51. Further, the periphery of the fitting bore 51 is provided with a plurality of locating recesses 52 corresponding to the locating posts 14. Once the main member 11 faces a lateral side of the circuit board 50 is inserted into the fitting bore 51, the elastic hooks 12 resiliently engage with another lateral side of the circuit board 50 and the locating posts 14 fit with the locating recesses 52 such that the circuit board 50 is capable of engaging with the first insulation frame 10 firmly.

The slit edges at two lateral sides of the respective elastic hook 12 increase flexibility of the respective elastic hook 12 such that the elastic hooks 12 provide larger displacement for engaging with the circuit board 50 to prevent the elastic hooks 12 from ruptures or avoid the fitting bore 51 breaking. Meanwhile, the paint coated coils 40 is incapable of breaking caused by swinging motor and the circuit board 50 can be retained at the base of a fan frame securely without falling off.

Furthermore, it is appreciated that the silicone sheet set 30 is attached to the main member 11 of the first insulation frame 10 circumferentially via the catching parts 18 in addition to be held by the first insulation frame 10 and the second insulation frame 20 axially. Besides, the first catching parts 18 make the first protruding plates 17 thicker to prevent the first protruding plates 17 from being deformed and enhance firmness of the silicone sheet set 30 in the first insulation frame 10. In this way, the problems such as noise and coil break can be improved substantially too.

While the invention has been described with referencing to preferred embodiments thereof, it is to be understood that modifications or variations may be easily made without departing from the spirit of this invention, which is defined by the appended claims.

What is claimed is:

1. An insulation frame device for a stator in a motor, comprising:
an insulation frame with a first and second lateral sides, providing a main member with a bore at the first lateral side;
a plurality of extension plates, extending radially from a circumferential outer surface of the main member; and
two outer circular plates, being disposed at a free end of the respective extension plate, and extending outward circumferentially and oppositely such that a U-shaped space is formed between every two adjacent extension plates respectively;
characterized in that a far end of the main member provides a plurality of elastic hooks slightly jutting out of the far end and two lateral sides of the respective elastic hook has a slit edge; and a U-shaped first protruding plate is disposed at the second lateral side and attached to the respective two adjacent extension plates with a catching part at the bottom of the first protruding plate to surround the bore.

2. The insulation frame device for a stator in a motor as defined in claim 1, wherein the a second protruding plate is provided at free end of the respective extension plate between the two opposite circular plates and the second protruding plate vertically extending outward from the first lateral side.

3. The insulation frame device for a stator in a motor as defined in claim 1, wherein the outer circumferential surface of the main member is provided with a plurality of locating posts along an axial direction of the main member.

4. The insulation frame device for a stator in a motor as defined in claim 1, wherein a containing groove is formed between every two of the first protruding plates.
